(19) United States
(12) Patent Application Publication
(10) Pub. No.: US 2024/0339363 A1
(43) Pub. Date: Oct. 10, 2024

(54) METHOD OF AND APPARATUS FOR PROCESSING WORKPIECE

(71) Applicant: DISCO CORPORATION, Tokyo (JP)

(72) Inventor: Kazuma SEKIYA, Tokyo (JP)

(21) Appl. No.: 18/611,952

(22) Filed: Mar. 21, 2024

(30) Foreign Application Priority Data
Apr. 10, 2023 (JP) 2023-063611

(51) Int. Cl. H01L 21/66; G05B 19/402; H01L 21/67; H01L 21/78

(52) U.S. Cl. CPC H01L 22/12; G05B 19/402; H01L 21/67092; H01L 21/67288; H01L 21/78; G05B 2219/42249

(57) ABSTRACT

A method of processing a workpiece to divide the workpiece into a plurality of device chips includes a dividing step of dividing a workpiece held on a holding table to produce a plurality of device chips from the workpiece, an image capturing step of capturing an image of the workpiece while the dividing step is being carried out or after the dividing step has been carried out, a detecting step of detecting from the image whether there is a chip fly-off from the workpiece or not and a chip fly-off region where a chip fly-off has occurred, and a warning step of warning of at least either one of a cause of the chip fly-off and a countermeasure against chip fly-offs.

### BACKGROUND OF THE INVENTION

### Field of the Invention

The present invention relates to a method of and an apparatus for processing a workpiece to divide the workpiece into a plurality of device chips.

### Description of the Related Art

There has been known a method of and an apparatus for processing a workpiece having a plurality of devices formed in respective areas demarcated on a face side thereof by a grid of projected dicing line to manufacture a plurality of individual device chips including the respective devices by dividing the workpiece along the projected dicing lines (see, for example, Japanese Patent Laid-open No. 2018-093042).

### SUMMARY OF THE INVENTION

The method of and the apparatus for processing the workpiece may allow device chips to fly off at a time at which the workpiece is divided into the device chips, causing what is generally called chip fly-offs. Japanese Patent Laid-open No. 2018-093042 discloses a technology for capturing an image of a workpiece while the workpiece is being processed or after the workpiece has been processed and detecting chip fly-off regions in the captured image in order to detect device chip fly-offs from the workpiece. However, the disclosed technology is problematic in that an operator is required to analyze causes of chip fly-offs and to review countermeasures for preventing device chips from flying off from the workpieces.

It is therefore an object of the present invention to provide a method of and an apparatus for processing a workpiece while facilitating an analysis of causes of chip fly-offs and a review of countermeasures for preventing device chips from flying off the workpiece.

In accordance with an aspect of the present invention, there is provided a method of processing a workpiece to divide the workpiece into a plurality of device chips, including a dividing step of dividing a workpiece held on a holding table to produce a plurality of device chips from the workpiece, an image capturing step of capturing an image of the workpiece while the dividing step is being carried out or after the dividing step has been carried out, a detecting step of detecting from the image whether there is a chip fly-off from the workpiece or not and a chip fly-off region where a chip fly-off has occurred, and a warning step of warning of at least either one of a cause of the chip fly-off and a countermeasure against chip fly-offs according to a region where the chip fly-off has been detected.

Preferably, in a case in which chip fly-offs have been detected in one region of at least a desired number of workpieces in the detecting step, the warning step includes a step of warning of foreign matter deposited on a holding surface of the holding table.

Preferably, in a case in which chip fly-offs have been detected in one region of at least a desired number of workpieces in the detecting step, the warning step includes a step of proposing cleaning a holding surface of the holding table.

Preferably, the dividing step includes a step of cutting the workpiece with a cutting blade while cutting water is supplied to a processing spot where the cutting blade cuts the workpiece, and in a case in which a chip fly-off has been detected from an outer edge of the workpiece in the detecting step, the warning step includes a step of warning of a high flow rate for the cutting water.

Preferably, the dividing step includes a step of cutting the workpiece with a cutting blade while cutting water is supplied to a processing spot where the cutting blade cuts the workpiece, and in a case in which a chip fly-off has been detected from an outer edge of the workpiece in the detecting step, the warning step includes a step of proposing adjusting a flow rate for the cutting water.

Preferably, in a case in which a chip fly-off has been detected from an outer edge of the workpiece in the detecting step, the warning step includes a step of proposing forming in the dividing step a dividing groove in the workpiece up to a position spaced a predetermined distance inwardly from the outer edge of the workpiece such that the dividing groove terminates short of the outer edge of the workpiece in a region where the chip fly-off has occurred.

Preferably, the dividing step includes a step of cutting the workpiece with a cutting blade, and in a case in which a chip fly-off has been detected from an outer edge of the workpiece in the detecting step, the warning step includes a step of proposing in the dividing step lowering a processing feed speed at which the cutting blade and the workpiece are processing-fed relatively to each other along a projected dicing line established on the workpiece in a region where the chip fly-off has occurred.

In accordance with another aspect of the present invention, there is provided an apparatus for processing a workpiece to divide the workpiece into a plurality of device chips, including a holding table for holding a workpiece thereon, a dividing unit which divides the workpiece held on the holding table to produce a plurality of device chips from the workpiece, an image capturing unit which captures an image of the workpiece while the workpiece is being divided by the dividing unit or after the workpiece has been divided by the dividing unit, and a controller. The controller includes a detecting section which detects a chip fly-off region where a chip fly-off has occurred by processing an image captured of the workpiece by the image capturing unit, and a warning section which warns of at least either one of a cause of the chip fly-off and a countermeasure against chip fly-offs according to the chip fly-off region detected by the detecting section.

According to the present invention, as at least either one of causes of chip fly-offs and countermeasures against chip fly-offs is determined and warned of, it is easy for the operator to analyze causes of chip fly-offs and countermeasures against chip fly-offs.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating a configuration example of an apparatus for processing a workpiece according to an embodiment of the present invention that carries out a method of processing a workpiece according to the embodiment;

FIG. 2 is a perspective view illustrating an example of a workpiece to be processed by the method of processing the workpiece according to the embodiment and the apparatus illustrated in FIG. 1;

FIG. 3 is a side elevational view illustrating structural details of a dividing unit of the apparatus illustrated in FIG. 1;

FIG. 4 is a side elevational view illustrating by way of example the manner in which the dividing unit of the apparatus illustrated in FIG. 1 operates;

FIG. 5 is a side elevational view illustrating by way of example the manner in which the dividing unit of the apparatus illustrated in FIG. 1 operates;

FIGS. 6A and 6B are diagrams illustrating by way of example images captured by an image capturing assembly of the apparatus illustrated in FIG. 1;

FIGS. 7A and 7B are diagrams illustrating by way of example images captured by the image capturing assembly of the apparatus illustrated in FIG. 1;

FIG. 8 is a diagram illustrating by way of example a database stored by a controller of the apparatus illustrated in FIG. 1;

FIG. 9 is a flowchart of a processing sequence of the method of processing a workpiece according to the embodiment;

FIG. 10 is a diagram illustrating by way of example a screen displayed in a warning step of the processing sequence illustrated in FIG. 9;

FIG. 11 is a diagram illustrating by way of example an image displayed in the warning step of the processing sequence illustrated in FIG. 9;

FIGS. 12A and 12B are diagrams illustrating by way of example countermeasures proposed in the warning step of the processing sequence illustrated in FIG. 9; and

FIGS. 13A and 13B are diagrams illustrating by way of example countermeasures proposed in the warning step of the processing sequence illustrated in FIG. 9.

### DETAILED DESCRIPTION OF THE PREFERRED EMBODIMENT

A preferred embodiment of the present invention will be described in detail hereinbelow with reference to the accompanying drawings. The present invention is not limited to the details of the embodiment described below. The components described below cover those which could easily be anticipated by those skilled in the art and those which are essentially identical to those described below. Further, the arrangements described below can be combined in appropriate manners. Various omissions, replacements, or changes of the arrangements may be made without departing from the scope of the present invention. In the description below, those components that are identical to each other are denoted by identical reference characters.

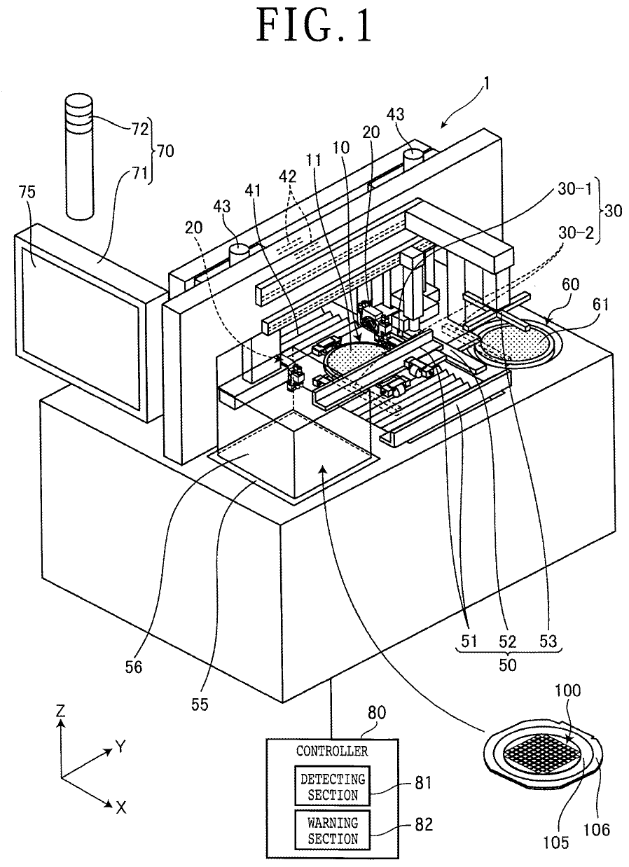

A method of and an apparatus for processing a workpiece according to an embodiment of the present invention will be described below with reference to the accompanying drawings. FIG. 1 illustrates in perspective a configuration example of the apparatus, denoted by 1, for processing a workpiece according to the present embodiment. The apparatus 1, also referred to as the processing apparatus 1, is illustrated in reference to a three-dimensional coordinate system having an X-axis, a Y-axis, and a Z-axis. The X-axis, which represents processing feed directions, and the Y-axis, which represents indexing feed directions, extend horizontally and perpendicularly to each other. The Z-axis, which represents incising feed directions, extends vertically and perpendicularly to the X-axis and the Y-axis.

As illustrated in FIG. 1, the processing apparatus 1 includes a holding table 10, a pair of dividing units 20, an image capturing assembly 30, an X-axis moving unit 41, a pair of Y-axis moving units 42, a pair of Z-axis moving units 43, a delivering unit 50, a cassette rest base 55, a cleaning unit 60, a signaling assembly 70, and a controller 80.

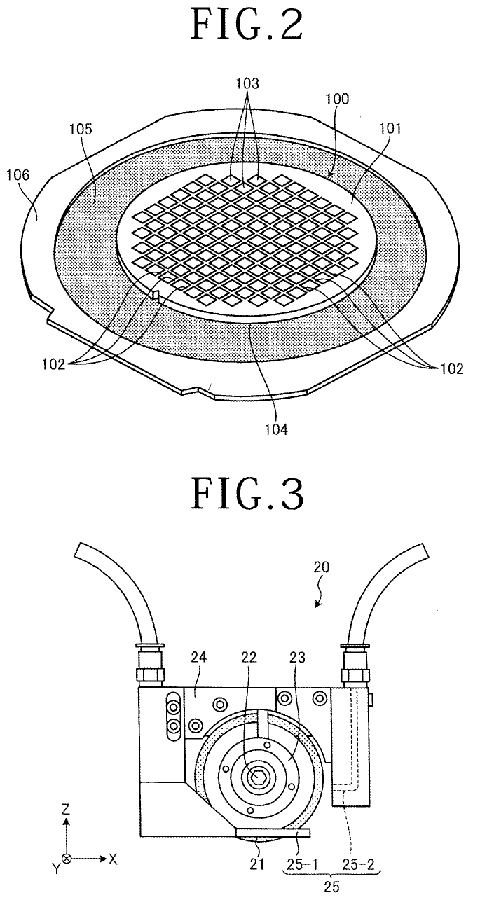

FIG. 2 illustrates in perspective an example of a workpiece to be processed by the method of processing a workpiece according to the present embodiment and the processing apparatus 1 illustrated in FIG. 1. As illustrated in FIG. 2, the workpiece, denoted by 100, includes a wafer such as a semiconductor wafer or an optical device wafer shaped as a circular plate made of a base material such as silicon, sapphire, silicon carbide (SiC), gallium arsenide, or glass, for example. The workpiece 100 has a plurality of devices 103 formed in respective areas demarcated on a flat face side 101 thereof by a grid of projected dicing lines 102 established on the face side 101. The workpiece 100 will be divided along the projected dicing lines 102 by the dividing unit 20 into a plurality of device chips, also referred to simply as chips, including the respective devices 103.

The workpiece 100 has a reverse side 104 opposite the face side 101, and a circular adhesive tape 105 is affixed to the reverse side 104. Specifically, the adhesive tape 105 has an upper adhesive surface affixed to the reverse side 104. The upper adhesive surface of the adhesive tape 105 has an outer edge portion to which an annular frame 106 is affixed. The workpiece 100 is disposed centrally in a circular opening of the annular frame 106. Therefore, the workpiece 100 is supported on the annular frame 106 by the adhesive tape 105 for easy handling. However, the adhesive tape 105 and the annular frame 106 may not necessarily be combined with the workpiece 100. According to the present invention, the workpiece 100 may alternatively be a rectangular packaged substrate with a plurality of devices encapsulated by a resin thereon, a ceramic plate, or a glass plate, for example.

As illustrated in FIG. 1, the holding table 10 includes a disk-shaped frame having a recess defined therein and a disk-shaped suction member fitted in the recess. The suction member of the holding table 10 is made of porous ceramic, for example, having a number of pores and is fluidly connected to a vacuum suction source, not depicted, through a vacuum suction channel, not depicted. The suction member has an upper surface functioning as a holding surface 11 for holding the workpiece 100 placed thereon under suction by a negative pressure introduced from the vacuum suction source. According to the present embodiment, the workpiece 100 is placed on the holding surface 11 with the face side 101 facing upwardly, and the holding surface 11 holds the workpiece 100 placed thereon under the negative pressure applied from the vacuum suction source via the adhesive tape 105 to the reverse side 104 of the workpiece 100. The holding surface 11 and the upper surface of the frame of the holding table 10 lie flush with each other parallel to an XY plane that is defined as a horizontal plane by the X-axis and the Y-axis. The holding table 10 is movable horizontally along the X-axis by the X-axis moving unit 41. The holding table 10 is also rotatable about the Z-axis that extends vertically and perpendicularly to the XY plane by a rotary actuator, not depicted, coupled to the holding table 10.

FIG. 3 illustrates in side elevation structural details of each of the dividing units 20 of the processing apparatus 1 illustrated in FIG. 1. The dividing unit 20 divides the workpiece 100 held on the holding table 10 in a dividing process, i.e., a cutting process according to the present embodiment. According to the present embodiment illustrated in FIGS. 1 and 3, the dividing unit 20 functions as a cutting unit including a spindle 22 that is rotatable about its longitudinal central axis by a rotary actuator such as an electric motor, not depicted, connected to the spindle 22. The spindle 22 has a distal end on which a cutting blade 21 is mounted. When the spindle 22 is rotated about its longitudinal central axis by the rotary actuator, it rotates the cutting blade 21 to cut the workpiece 100 along each of the projected dicing lines 102, thereby dividing the workpiece 100 into the device chips. The dividing unit 20 is movable horizontally along the Y-axis by the Y-axis moving unit 42 and is also vertically movable along the Z-axis by one of the Z-axis moving units 43. As illustrated in FIG. 1, the processing apparatus 1 may be referred to as a two-spindle dicer, i.e., a dual facing-type processing apparatus, including the two dividing units 20 as two cutting units.

As illustrated in FIG. 3, each of the dividing units 20 includes the cutting blade 21, the spindle 22, a mount 23, a blade cover 24, and a cutting water supply nozzle assembly 25. The cutting blade 21 is mounted on the distal end of the spindle 22 by the mount 23. When the rotary actuator is energized, it rotates the spindle 22 and hence the cutting blade 21, enabling the cutting blade 21 to cut the workpiece 100 held on the holding table 10. The central axis about which the spindle 22 is rotatable by the rotary actuator connected to the spindle 22 extends parallel to the Y-axis. The distal end of the spindle 22 is coupled to the mount 23, and the cutting blade 21 is fastened on the mount 23. The cutting blade 21 is thus mounted on the distal end of the spindle 22 by the mount 23. When rotated by the rotary actuator, the spindle 22 rotates the cutting blade 21 mounted on the distal end thereof about the central axis parallel to the Y-axis. The mount 23 is coupled to the spindle 22 and supports the cutting blade 21 on the distal end of the spindle 22.

The blade cover 24 is fixed to a distal-end side of a spindle housing that houses most of the spindle 22 therein, leaving its distal end exposed. As illustrated in FIG. 3, the blade cover 24 covers upper, front, and rear portions of the cutting blade 21 mounted on the distal end of the spindle 22. The cutting water supply nozzle assembly 25 is mounted on the blade cover 24 and directed downwardly. The cutting water supply nozzle assembly 25 is fluidly connected to a cutting water supply source, not depicted, via a plurality of water channels defined in the blade cover 24. The cutting water supply nozzle assembly 25 ejects cutting water supplied from the cutting water supply source toward a processing spot, i.e., a processing zone, on the workpiece 100 held on the holding table 10 while the workpiece 100 is being processed by the rotating cutting blade 21. The cutting water supplied from the cutting water supply source is pure water or pure water containing CO₂ and a surfactant, for example.

According to the present embodiment, the cutting water supply nozzle assembly 25 includes a first nozzle 25-1 and a second nozzle 25-2. As illustrated in FIG. 3, the first nozzle 25-1 is provided as a blade cooler nozzle for ejecting cutting water supplied from the cutting water supply source via one of the water channels defined in the blade cover 24 toward a side portion of an outer circumferential cutting edge of the cutting blade 21. Specifically, the first nozzle 25-1 ejects the cutting water toward a region of the outer circumferential cutting edge of the cutting blade 21 that is moving near the processing spot on the workpiece 100.

The second nozzle 25-2 is provided as a shower nozzle for ejecting cutting water supplied from the cutting water supply source via another one of the water channels defined in the blade cover 24 toward a front portion of the outer circumferential cutting edge of the cutting blade 21. Specifically, the second nozzle 25-2 ejects the cutting water toward a region of the outer circumferential cutting edge of the cutting blade 21 that is moving forwardly, i.e., upstream, of the processing spot on the workpiece 100 along the direction in which the cutting blade 21 is rotated.

The dividing unit 20 operates as follows. While cutting water is being supplied from the cutting water supply nozzle assembly 25 to the processing spot on the workpiece 100, the spindle 22 is rotated to rotate the cutting blade 21 mounted on the distal end of the spindle 22 about its central axis parallel to the Y-axis, and the X-axis moving unit 41 moves the workpiece 100 held on the holding table 10 along the X-axis relatively to the cutting blade 21. The cutting blade 21 now cuts the workpiece 100 along one of the projected dicing lines 102 to cut a dividing groove in the workpiece 100 along the projected dicing line 102, thereby dividing the workpiece 100 along the projected dicing line 102.

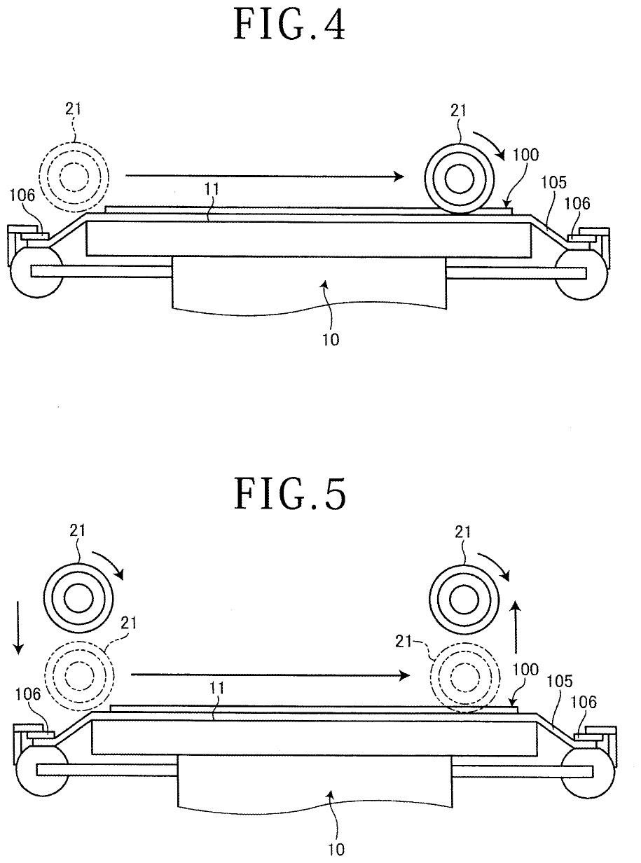

FIGS. 4 and 5 illustrate in side elevation by way of example the manner in which each of the dividing units 20 of the processing apparatus 1 illustrated in FIG. 1 operates. Providing no particular dividing or cutting conditions have been established by the controller 80, as illustrated in FIG. 4, the dividing unit 20 performs a cutting process for forming a dividing groove in the workpiece 100 by rotating the cutting blade 21 and enabling the cutting blade 21 to start cutting the workpiece 100 at an outer edge thereof and moving the cutting blade 21 across the workpiece 100 in a processing feed direction along one of the projected dicing lines 102 to cut the workpiece 100 all the way up to an opposite edge thereof along the projected dicing line 102. In this manner, a dividing groove is formed across the workpiece 100 all the way along the projected dicing line 102 in the cutting process.

Providing particular dividing or cutting conditions for cutting the workpiece 100 along one of the projected dicing lines 102 to a position short of a certain outer edge thereof to avoid cutting a region including the outer edge of the workpiece 100 have been established by the controller 80, as illustrated in FIG. 5, the dividing unit 20 performs another cutting process for forming a shorter dividing groove in the workpiece 100 by rotating the cutting blade 21 at a position above an outer edge of the workpiece 100, lowering the cutting blade 21 in an incising feed direction along the Z-axis toward a position where the workpiece 100 starts to be cut until the cutting blade 21 cuts into the workpiece 100 by a predetermined depth from the face side 101, thereafter moving the cutting blade 21 across the workpiece 100 in a processing feed direction along the projected dicing line 102 up to a position where the workpiece 100 stops being cut, and then lifting the cutting blade 21 along the Z-axis away from the workpiece 100. In the cutting process illustrated in FIG. 5, after the cutting blade 21 is lowered until it cuts into the workpiece 100 by the predetermined depth from the face side 101 at the position where the workpiece 100 starts to be cut on the outer edge thereof, the cutting blade 21 is moved across the workpiece 100 in the processing feed direction along the projected dicing line 102 up to the position where the workpiece 100 stops being cut. The position where the workpiece 100 stops being cut is spaced a predetermined distance radially inwardly from the certain outer edge of the workpiece 100. Therefore, the cutting blade 21 avoids cutting a region including the certain outer edge of the workpiece 100. In this manner, a shorter dividing groove is formed in the workpiece 100 along the projected dicing line 102 in the cutting process illustrated in FIG. 5.

The predetermined distance by which the position where the workpiece 100 stops being cut is spaced radially inwardly from the certain outer edge of the workpiece 100 refers to a distance large enough to keep the shorter dividing groove from being developed to the outer edge of the workpiece 100 due to external forces acting on the workpiece 100, e.g., vibrations while the workpiece 100 is being delivered and rotary motions while the workpiece 100 is being cleaned, in various processes performed by the processing apparatus 1 other than the dividing process performed by the dividing unit 20, i.e., the cutting process according to the present embodiment.

In the other cutting process for forming a shorter dividing groove in the workpiece 100 depicted in FIG. 5, the dividing unit 20 cuts the outer edge of the workpiece 100 at the position where the workpiece 100 starts to be cut and avoids cutting the outer edge of the workpiece 100 only at the position where the workpiece 100 stops being cut, keeping the region including the latter outer edge uncut at the latter position. According to the present invention, however, the dividing unit 20 may avoid cutting the outer edge of the workpiece 100 only at the position where the workpiece 100 starts to be cut, keeping a region including the outer edge uncut at that position, or may avoid cutting the outer edges of the workpiece 100 both at the position where the workpiece 100 starts to be cut and at the position where the workpiece 100 stops being cut, keeping regions including the outer edges uncut both at those positions.

According to the present invention, the dividing unit 20 is not limited to the cutting unit described above. The dividing unit 20 may alternatively be a laser processing unit including a laser beam irradiator for applying a laser beam to the workpiece 100. The laser processing unit applies a laser beam having a wavelength absorbable by the workpiece 100 from the laser beam irradiator to the workpiece 100 on the holding table 10 along one of the projected dicing lines 102 of the workpiece 100 to perform an ablating process for ablating, i.e., sublimating or evaporating, the workpiece 100 at the face side 101, thereby dividing the workpiece 100 along the projected dicing line 102. The dividing unit 20 may further alternatively be a laser processing unit for applying a laser beam having a wavelength transmittable through the workpiece 100 on the holding table 10 to the workpiece 100 along one of the projected dicing lines 102 thereof to form modified layers and cracks extending from the modified layers toward the face side 101 and the reverse side 104 of the workpiece 100 in the workpiece 100 along the projected dicing line 102, thereby dividing the workpiece 100 into individual device chips along the modified layers and the cracks. The modified layers represent regions whose density, refractive index, mechanical strength, or other physical properties are different from those of surrounding regions and may be referred to as melted regions, crack regions, dielectric-breakdown regions, varied-refractive-index regions, or regions where those regions are coexistent.

According to still another alternative, the dividing unit 20 may be a grinding unit having a spindle on which a grinding wheel including grindstones is rotatably mounted. The grinding unit performs a grinding process on the workpiece 100 that has division initiating points such as modified layers or dividing grooves formed therein along the projected dicing lines 102. The grinding unit operates by grinding the reverse side 104 of the workpiece 100 with the grindstones to divide the workpiece 100 into individual device chips along the projected dicing lines 102. According to still further alternative, the dividing unit 20 may be a polishing unit having a spindle on which a polishing pad is rotatably mounted. The polishing unit performs a polishing process on the workpiece 100 that has division initiating points such as modified layers or dividing grooves formed therein along the projected dicing lines 102. The polishing unit operates by polishing the reverse side 104 of the workpiece 100 with the polishing pad to divide the workpiece 100 into individual device chips along the projected dicing lines 102. When the workpiece 100 is ground or polished as described above, cracks are developed from the modified layers in the workpiece 100 due to shocks caused in the grinding or polishing process, allowing the workpiece 100 to be divided along the modified layers. The dividing grooves represent half-cut grooves that are cut in the workpiece 100 from the face side 101 but are not deep enough to extend to the reverse side 104 all the way across the workpiece 100. When the workpiece 100 is ground or polished from the reverse side 104 until the dividing grooves are exposed, the workpiece 100 is divided along the dividing grooves. When the modified layers or the dividing grooves have been formed in the workpiece 100 along all the projected dicing lines 102, the workpiece 100 can be divided into individual device chips along the modified layers or the dividing grooves.

The image capturing assembly 30 includes image capturing elements for capturing images of the workpiece 100. Each of the image capturing elements may include a charge-coupled-device (CCD) image sensor or a complementary metal-oxide semiconductor (CMOS) image sensor, for example. The image capturing assembly 30 captures an image of the workpiece 100 while the workpiece 100 is being divided or after the workpiece 100 has been divided. The image capturing assembly 30 has an image capturing field large enough to capture a single image representing the entire face side 101 of the workpiece 100. Alternatively, the image capturing assembly 30 scans the entire face side 101 of the workpiece 100 by moving relatively to the workpiece 100 to capture images representing the entire face side 101 of the workpiece 100. The image capturing assembly 30 outputs the captured image or images to the controller 80. The image capturing assembly 30 may capture either a single image or a plurality of images representing the entire face side 101 of the workpiece 100. When the controller 80 is supplied with a plurality of images representing the entire face side 101 of the workpiece 100 from the image capturing assembly 30, the controller 80 processes or combines the images into a single image. According to the present embodiment, the image capturing assembly 30 includes an image capturing unit 30-1 and an image capturing unit 30-2.

The image capturing unit 30-1 captures an image of the workpiece 100 held on the holding table 10. The image thus captured will be used in an alignment process for positioning the workpiece 100 and the dividing unit 20 with respect to each other. The image capturing unit 30-1 captures an image of the face side 101 of the workpiece 100 held on the holding table 10. The image thus captured will be used in a checking process for automatically checking whether the workpiece 100 has been processed in a proper range on the workpiece 100 or not. According to the present embodiment, the image capturing unit 30-1 is fixed in position adjacent to the dividing unit 20 and movable in unison with the dividing unit 20.

According to the present embodiment, the image capturing unit 30-2 includes a line camera including a line sensor of image capturing elements arrayed in a single row or a plurality of rows along the X-axis. The image capturing unit 30-2 is disposed above a delivery path along which the workpiece 100 is to be delivered from a spinner table 61 of the cleaning unit 60 onto a pair of rails 51. The image capturing unit 30-2 captures an image of the workpiece 100 while the workpiece 100 is being delivered from the spinner table 61 of the cleaning unit 60 onto the rails 51. Alternatively, the image capturing unit 30-2 may be disposed above a delivery path along which the workpiece 100 is to be delivered from the rails 51 into a cassette 56 that is placed on the cassette rest base 55. The image capturing unit 30-2 thus disposed captures an image of the workpiece 100 while the workpiece 100 is being delivered from the spinner table 61 into the cassette 56 on the cassette rest base 55. The image capturing unit 30-2 is installed on a delivery arm 52 for delivering the workpiece 100 and may capture an image of the workpiece 100 by scanning the workpiece 100 on the spinner table 61 of the cleaning unit 60 or the rails 51 with the delivery arm 52.

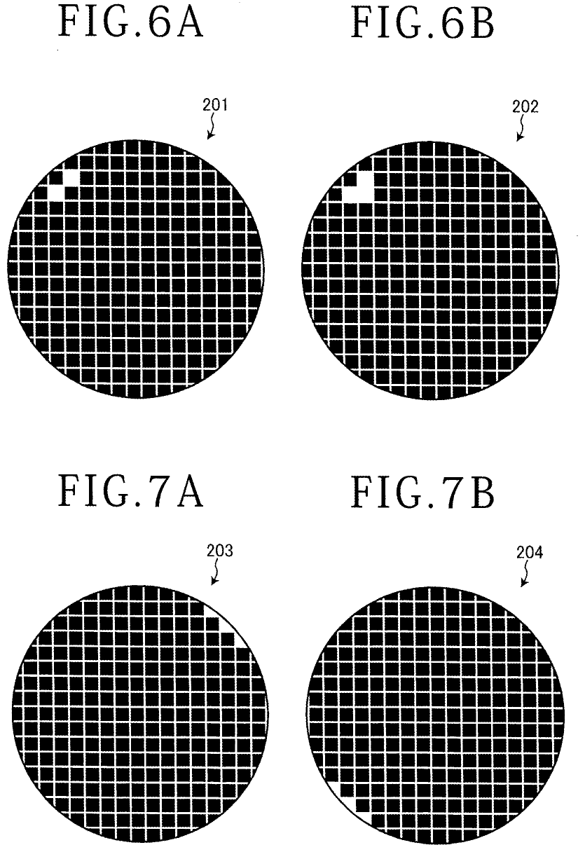

FIGS. 6A through 7B illustrate by way of example images captured by the image capturing assembly 30 of the processing apparatus 1 illustrated in FIG. 1. After the dividing process carried out on the workpiece 100, the image capturing assembly 30 captures images 201, 202, 203, and 204 of the face sides 101 of workpieces 100 as illustrated respectively in FIGS. 6A through 7B. In each of the images 201, 202, 203, and 204, the upper adhesive surface of the adhesive tape 105 is represented by pixels having a luminance value equal to or higher than a predetermined threshold value, and the devices 103 of the workpiece 100 have respective exposed upper surfaces represented by pixels having a luminance value lower than the predetermined threshold value. Accordingly, the dividing grooves formed in the workpiece 100 along the projected dicing lines 102 and the chip fly-off regions of the workpiece 100 from which the device chips have been flown off are represented by pixels having a luminance value equal to or higher than the predetermined threshold value, and the regions of the workpiece 100 from which no device chips have been flown off are represented by pixels having a luminance value lower than the predetermined threshold value. The images 201 and 202 illustrated respectively in FIGS. 6A and 6B are images of workpieces 100 where device chip fly-offs have occurred in similar regions inside of the outer edges of the workpieces 100, whereas the images 203 and 204 illustrated respectively in FIGS. 7A and 7B are images of workpieces 100 where device chip fly-offs have occurred in the outer edges of the workpieces 100.

The luminance value representing the adhesive surface of the adhesive tape 105 and the luminance value representing the exposed upper surfaces of the devices 103 of the workpiece 100 are different from each other by a sufficiently appreciable level. Therefore, the predetermined threshold value referred to above may be preset by the operator as a luminance value that is appreciably lower than the luminance value representing the adhesive surface of the adhesive tape 105 and appreciably higher than the luminance value representing the exposed upper surfaces of the devices 103 of the workpiece 100, and registered in the controller 80. In a case in which these luminance values are not appreciably different from each other, the controller 80 may perform image processing on the captured images to distinguish the exposed upper surfaces of the devices 103 and the adhesive surface of the adhesive tape 105 from each other.

According to the present embodiment, the luminance of the images 201, 202, 203, and 204 is defined in a plurality of gradations, e.g., 256 gradations, and expressed by integral values ranging from 0 to 255. The darkest luminance value is expressed by the minimum gradation of 0 and the brightest luminance value is expressed by the maximum gradation of 255, with intermediate luminance values varying such that the brighter, the larger the luminance value.

The X-axis moving unit 41, the Y-axis moving units 42, and the Z-axis moving units 43 move the holding table 10 and the dividing units 20 relatively to each other along the X-axis, the Y-axis, and the Z-axis respectively. According to the present embodiment, the X-axis moving unit 41 moves the holding table 10 along the X-axis relatively to the dividing units 20. According to the present embodiment, the Y-axis moving units 42 and the Z-axis moving units 43 move the dividing units 20 respectively along the Y-axis and the Z-axis relatively to the holding table 10. Each of the X-axis moving unit 41, the Y-axis moving units 42, and the Z-axis moving units 43 is a known ball screw mechanism having an electric motor, a ball screw, and a pair of guides.

According to the present embodiment, the delivering unit 50 includes the rails 51, the delivery arm 52, and a delivery arm 53. The rails 51 are movable toward and away from each other while being kept parallel to each other, and can hold the workpiece 100 with the annular frame 106 interposed therebetween. The delivery arm 52 has a gripper for gripping sideways the annular frame 106 mounted on the workpiece 100 to indirectly grip the workpiece 100 such that the image capturing unit 30-2 can capture an image of the workpiece 100 from above. The delivery arm 52 delivers the workpiece 100 gripped by the gripper between a position within the cassette 56 on the cassette rest base 55 and a position on the rails 51 and also between a position on the spinner table 61 of the cleaning unit 60 and a position on the rails 51. The delivery arm 53 has a suction holder for holding under suction the annular frame 106 mounted on the workpiece 100 from above to indirectly hold the workpiece 100 from above. The delivery arm 53 delivers the workpiece 100 held under suction by the suction holder between a position on the holding table 10 and a position on the rails 51 and also between a position on the holding table 10 and a position on the spinner table 61 of the cleaning unit 60. The cassette rest base 55 is a rest base for supporting the cassette 56 placed thereon as a receptacle for housing a plurality of workpieces 100 therein, and is vertically movable to lift and lower the cassette 56 placed thereon along the Z-axis.

The cleaning unit 60 includes the spinner table 61. The spinner table 61 is identical in structure to the holding table 10. When the workpiece 100 is placed on the spinner table 61 with the face side 101 facing upwardly, the spinner table 61 holds the workpiece 100 placed thereon under a negative pressure applied via the adhesive tape 105 to the reverse side 104 of the workpiece 100. The cleaning unit 60 cleans the workpiece 100 held on the spinner table 61, removing contaminants such as swarf produced and attached to the workpiece 100 when it was divided by the dividing unit 20, for example.

According to the example of the present embodiment illustrated in FIG. 1, the signaling assembly 70 includes a display unit 71 and a lighting unit 72. The display unit 71 is mounted on a cover, not depicted, of the processing apparatus 1 and has a display surface facing outwardly. The display unit 71 displays in a manner visually recognizable by the operator screens for setting various conditions with respect to the various processes of the processing apparatus 1, such as the dividing process of the dividing units 20 and the image capturing process of the image capturing assembly 30, acquired images and data, various decisions made by the controller 80, results detected by a detecting section 81, to be described later, of the controller 80, and warnings issued by a warning section 82, to be described later, of the controller 80. The display unit 71 includes a display device such as a liquid crystal display device, for example. The display unit 71 includes an input unit 75 that can be used by the operator to enter information regarding the various conditions referred to above and information regarding the display of images, in the processing apparatus 1. The input unit 75 includes at least one of a touch panel incorporated in the display unit 71, a keyboard, and other input devices. The display unit 71 may not be fixed to the processing apparatus 1, but may be incorporated in a separate communication device that is connected to the processing apparatus 1 via a wireless or wired link.

The lighting unit 72 is mounted on an upper portion of the undepicted cover of the processing apparatus 1. According to the present embodiment, the lighting unit 72 includes light-emitting diodes, for example, and indicates in a manner recognizable by the operator errors that have occurred in the various processes of the processing apparatus 1, decisions, and warnings by way of lighting, blinking, or light hues. The signaling assembly 70 is not limited to the display unit 71 and the lighting unit 72, and may instead include a sounding unit including a speaker for producing sounds, for example. The sounding unit may indicate in a manner recognizable by the operator errors, decisions, and warnings to the operator by way of sounds.

The controller 80 controls operation of the various components of the processing apparatus 1 to enable the processing apparatus 1 to perform the various processes in the method of processing a workpiece according to the present embodiment. The controller 80 controls the image capturing assembly 30 to capture images of the workpiece 100 and obtain the captured images, i.e., the images 201, 202, 203, and 204, of the workpiece 100. In a case in which the image capturing assembly 30 is to scan the workpiece 100 to capture images thereof, the controller 80 also controls a moving unit, not depicted, for moving the image capturing assembly 30.

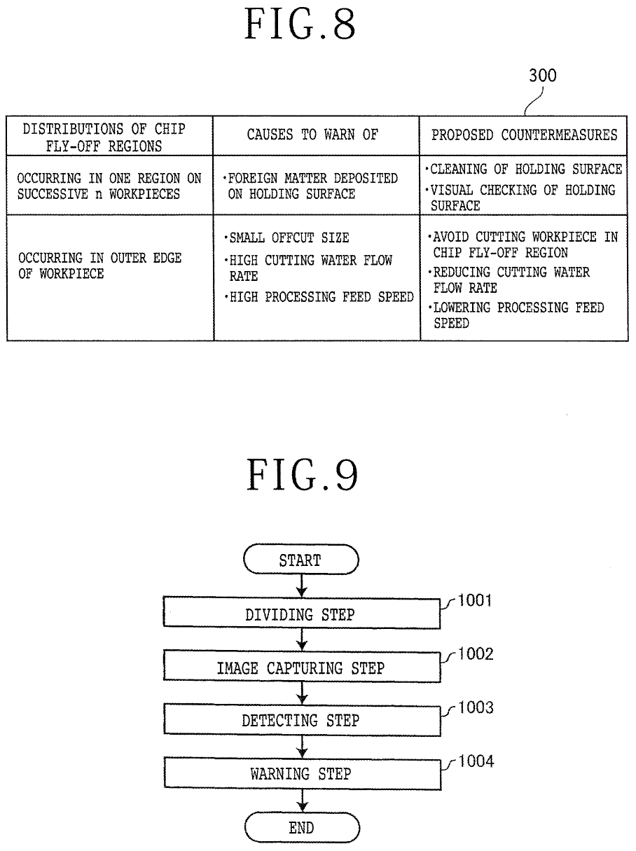

FIG. 8 illustrates by way of example a database 300 stored by the controller 80 of the processing apparatus 1 illustrated in FIG. 1. As illustrated in FIG. 8, the database 300 represents patterns of chip fly-off regions, causes of chip fly-offs in the patterns of the regions, and countermeasures for eliminating the causes, that are selectively associated with each other. At least either one of the causes and the countermeasures may be associated with one of the patterns of chip fly-off regions. In FIG. 8, “DISTRIBUTIONS OF CHIP FLY-OFF REGIONS” indicate patterns of regions where chip fly-offs have occurred, “CAUSES TO WARN OF” indicate information representing the causes of chip fly-offs in the patterns of the regions, and “PROPOSED COUNTERMEASURES” indicate information representing the countermeasures for eliminating the causes.

When a certain region of the holding surface 11 of the holding table 10 that is holding the workpiece 100 thereon has foreign matter deposited therein, the workpiece 100 is liable to cause a chip fly-off in a region thereof that corresponds to the certain region of the holding surface 11. In a case in which foreign matter is deposited on the holding surface 11 of the holding table 10, then the operator cleans the holding surface 11 to remove the deposited foreign matter or visually checks the holding surface 11 and removes the deposited foreign matter, thereby preventing device chips from flying off the workpiece 100. In the example of the database 300 according to the present embodiment illustrated in FIG. 8, a pattern of chip fly-offs occurring successively or with a high probability at a frequency equal to or larger than a predetermined value in one region of at least a desired number (n) of workpieces 100, a cause as foreign matter deposited on the holding surface 11, and a countermeasure of cleaning the holding surface 11 or visually checking the holding surface 11 are associated with each other.

When the dividing unit 20 divides the workpiece 100 including the outer edge thereof, the workpiece 100 is liable to cause chip fly-offs near the outer edge thereof due to offcuts from the outer edge that are smaller in size as the workpiece 100 is divided. Providing chip fly-offs occur for this reason, the operator can prevent chip fly-offs from occurring by performing the cutting process for forming a shorter dividing groove in the workpiece 100 that terminates a predetermined distance radially inwardly from the outer edge of the workpiece 100 in the region including the outer edge where chip fly-offs would otherwise tend to occur. In the example of the database 300 according to the present embodiment illustrated in FIG. 8, a pattern of chip fly-offs occurring near the outer edge of the workpiece 100, a cause of smaller offcuts, and a countermeasure of avoiding cutting the outer edge to keep it uncut in the region including the outer edge are associated with each other.

When the dividing unit 20 divides the workpiece 100 while cutting water is being supplied to the spot where the cutting blade 21 of the dividing unit 20 cuts the workpiece 100, if the cutting water is excessively supplied at a high flow rate, then offcuts produced from the outer edge of the workpiece 100 that are smaller in size as the workpiece 100 is divided tend to jump off due to the excessively supplied cutting water at a high flow rate, causing chip fly-offs. Providing chip fly-offs occur for this reason, the operator can prevent chip fly-offs from occurring by reducing the flow rate of the cutting water. In the example of the database 300 according to the present embodiment illustrated in FIG. 8, a pattern of chip fly-offs occurring from the outer edge of the workpiece 100, a cause of a high flow rate of cutting water, and a countermeasure of reducing the flow rate of cutting water are associated with each other.

When the dividing unit 20 divides the workpiece 100 while cutting water is being supplied to the spot where the cutting blade 21 of the dividing unit 20 cuts the workpiece 100, if the cutting blade 21 and the workpiece 100 are moved, i.e., processing-fed, relatively to each other along one of the projected dicing lines 102 at an excessively high processing feed speed, then offcuts produced from the outer edge of the workpiece 100 that are smaller in size as the workpiece 100 is divided tend to jump off due to the cutting blade 21 moving at the excessively high processing feed speed, causing chip fly-offs. Providing chip fly-offs occur for this reason, the operator can prevent chip fly-offs from occurring by lowering the processing feed speed. In the example of the database 300 according to the present embodiment illustrated in FIG. 8, a pattern of chip fly-offs occurring from the outer edge of the workpiece 100, a cause of an excessively high processing feed speed, and a countermeasure of lowering the processing feed speed are associated with each other.

According to the present embodiment, in the database 300 illustrated in FIG. 8, the causes of chip fly-offs and the countermeasures for eliminating the causes are associated with the pattern of chip fly-offs occurring successively or with a high probability in one region of at least a desired number (n) of workpieces 100 and the pattern of chip fly-offs occurring near the outer edge of the workpiece 100. However, the present invention is not limited to the database 300 illustrated in FIG. 8. Specifically, other patterns of chip fly-offs may be associated with causes of the chip fly-offs and countermeasures for eliminating the causes. According to the present embodiment, furthermore, the controller 80 stores the database 300 illustrated in FIG. 8 that is based on a cutting unit used as the dividing unit 20. The present invention is not limited to the database 300 based on a cutting unit used as the dividing unit 20. If the dividing unit 20 is a laser processing unit or the grinding unit, then the controller 80 stores a database that has been varied based on a laser processing unit or the grinding unit.

As illustrated in FIG. 1, the controller 80 includes the detecting section 81 and the warning section 82. The detecting section 81 detects chip fly-off regions from the images 201, 202, 203, and 204 captured by the image capturing assembly 30 according to an image process. Specifically, the detecting section 81 binarizes the images 201, 202, 203, and 204 captured by the image capturing assembly 30 with the luminance value of the predetermined threshold value, converts pixels having luminance values equal to or larger than the predetermined threshold value into pixels having the maximum luminance value of 255 and pixels having luminance values smaller than the predetermined threshold value into pixels having the minimum luminance value of 0, extracts regions of the pixels having the maximum luminance level except regions where the dividing grooves have been cut along the projected dicing lines 102, and detects the extracted regions as chip fly-off regions.

For example, the detecting section 81 detects two white square regions in an upper left portion of the workpiece 100 from the image 201 illustrated in FIG. 6A as chip fly-off regions. Further, the detecting section 81 detects three white square regions in an upper left portion of the workpiece 100 from the image 202 illustrated in FIG. 6B as chip fly-off regions. The detecting section 81 also detects three white triangular regions in an upper right portion of the workpiece 100 from the image 203 illustrated in FIG. 7A as chip fly-off regions. The detecting section 81 also detects three white triangular regions in a lower left portion of the workpiece 100 from the image 203 illustrated in FIG. 7B as chip fly-off regions.

The warning section 82 warns of at least either one of causes of and countermeasures against the chip fly-offs on the basis of the chip fly-off regions detected by the detecting section 81. Specifically, the warning section 82 refers to the database 300 illustrated in FIG. 8 that is stored in the controller 80 and determines whether a chip fly-off region detected by the detecting section 81 matches the pattern of one of the chip fly-off regions registered in the database 300. Then, if the chip fly-off region detected by the detecting section 81 is determined as matching the pattern of one of the chip fly-off regions registered in the database 300, then the warning section 82 warns of at least either one of the cause and the countermeasure that are associated with the pattern determined as matched in the database 300, and sends the warning to the signaling assembly 70 to enable the signaling assembly 70 to signal the warning. The warning section 82 may warn the operator of both the cause and the countermeasure. If there are a plurality of causes and countermeasures that are associated with the pattern determined as matched in the database 300, then the warning section 82 may warn the operator of the causes and the countermeasures simultaneously or selectively.

For example, when the images 201 and 202 illustrated in FIGS. 6A and 6B are captured from two successive workpieces 100, the detecting section 81 detects chip fly-off regions in the upper left portions of the two successive workpieces 100 in FIGS. 6A and 6B. Based on the detected chip fly-off regions, the warning section 82 determines that the detected chip fly-off regions match the pattern, registered in the database 300, of chip fly-off regions occurring successively or with a high probability in one region of at least a desired number (n) of workpieces 100, and warns of at least either the cause as foreign matter deposited on the holding surface 11 or the countermeasure of cleaning the holding surface 11 and visually checking the holding surface 11.

When the images 203 and 204 illustrated in FIGS. 7A and 7B are captured from two workpieces 100, the detecting section 81 detects chip fly-off regions in the outer edges of the two workpieces 100. Based on the detected chip fly-off regions, the warning section 82 determines that the chip fly-offs that have occurred match the pattern, registered in the database 300, of chip fly-off regions occurring in the outer edges of the workpieces 100. Then, the warning section 82 warns of at least either one of a cause as a small offcut size, a cause as a high flow rate of cutting water, a cause as a high processing feed speed, a countermeasure of avoiding cutting the outer edge to keep it uncut in the chip fly-off region, a countermeasure of reducing the flow rate of cutting water, and a countermeasure of lowering the processing feed speed.

According to the present embodiment, the controller 80 includes a computer system. The computer system has a processing device having a microprocessor such as a central processing unit (CPU), a storage device having a memory such as a read only memory (ROM) or a random access memory (RAM), and an input/output interface device. The processing device performs processing operations according to computer programs stored in the storage device of the controller 80, and generates and outputs control signals for controlling the processing apparatus 1 through the input/output interface device of the controller 80 to the various components of the processing apparatus 1. According to the present embodiment, the detecting section 81 and the warning section 82 have their functions carried out by the processing device of the controller 80 as it executes computer programs stored in the storage device.

The method of processing a workpiece according to the present embodiment will be described below with reference to the drawings. FIG. 9 is a flowchart of a processing sequence of the method of processing a workpiece according to the present embodiment. The method of processing a workpiece represents an example of an operational sequence carried out by the processing apparatus 1 according to the present embodiment. As illustrated in FIG. 9, the method of processing a workpiece includes a dividing step 1001, an image capturing step 1002, a detecting step 1003, and a warning step 1004. The method of processing a workpiece according to the present embodiment is summarized as follows. When the cassette 56 that houses a plurality of workpieces 100 that are undivided, i.e., are to be divided in the dividing process, is placed on the cassette rest base 55, the workpieces 100 housed in the cassette 56 are taken out and processed successively one at a time in each of the steps referred to above.

In the method of processing a workpiece according to the present embodiment, the dividing step 1001 is preceded by a holding step for holding one of the workpieces 100 from the cassette 56 on the holding surface 11 of the holding table 10. In the holding step, specifically, the controller 80 controls the delivering unit 50 to actuate the delivery arm 52 and unload one of the workpieces 100 from the cassette 56 to deliver the unloaded workpiece 100 along the rails 51 onto the holding surface 11 of the holding table 10. In the holding step, then, the controller 80 controls the holding table 10 to hold the workpiece 100 delivered to the holding surface 11 under suction on the holding surface 11.

The dividing step 1001 is a step of dividing the workpiece 100 held on the holding table 10 into a plurality of device chips having the respective devices 103. In the dividing step 1001, as illustrated in FIG. 4, for example, the controller 80 controls each of the dividing unit 20 to rotate the spindle 22 and rotate the cutting blade 21 mounted on the distal end of the spindle 22 about the central axis thereof parallel to the Y-axis while controlling the cutting water supply nozzle assembly 25 to supply cutting water to the spot where the cutting blade 21 processes, i.e., cuts the workpiece 100. At the same time, the controller 80 controls the X-axis moving unit 41 to move the cutting blade 21 along the X-axis relatively to the workpiece 100 on the holding table 10 and cut the workpiece 100 along one of the projected dicing lines 102 with the cutting blade, thus dividing the workpiece 100 along the projected dicing line 102. In the dividing step 1001, the controller 80 controls the dividing unit 20 to cut the workpiece 100 along all the projected dicing lines 102 thereon, dividing the workpiece 100 into the device chips having the respective devices 103 and cutoffs from the outer edge of the workpiece 100.

The image capturing step 1002 is a step of capturing an image of the workpiece 100 while the dividing step 1001 is being carried out or after the dividing step 1001 has been carried out. In the image capturing step 1002, the controller 80 controls the image capturing assembly 30 to capture an image, e.g., the image 201, 202, 203, or 204, of the workpiece 100 while the dividing step 1001 is being carried out or after the dividing step 1001 has been carried out. The phrase “while the dividing step 1001 is being carried out” represents a point of time after the workpiece 100 has been cut along some of the projected dicing lines 102. The phrase “after the dividing step 1001 has been carried out” represents a point of time after the workpiece 100 has been cut along all of the projected dicing lines 102.

In the image capturing step 1002 carried out while the dividing step 1001 is being carried out, the controller 80 controls the image capturing unit 30-1 to capture an image of the face side 101 of the workpiece 100 held on the holding table 10. In the image capturing step 1002 carried out after the dividing step 1001 has been carried out, the controller 80 may control the image capturing unit 30-1 to capture an image of the face side 101 of the workpiece 100 held on the holding table 10, or may control the image capturing unit 30-2 to capture an image of the face side 101 of the workpiece 100 held on the spinner table 61 of the cleaning unit 60 after the workpiece 100 has been delivered onto the spinner table 61 by the delivery arm 52 of the delivering unit 50 subsequently to the dividing step 1001 and then after the workpiece 100 has been cleaned by the cleaning unit 60, or may control the image capturing unit 30-2 to capture an image of the face side 101 of the workpiece 100 on the rails 51 after the workpiece 100 has been cleaned by the cleaning unit 60 subsequently to the dividing step 1001 and then while the workpiece 100 is being delivered onto the rails 51 or after the workpiece 100 has been delivered onto the rails 51 by the delivery arm 52 of the delivering unit 50.

The detecting step 1003 is a step of detecting whether there are chip fly-offs or not and detecting chip fly-off regions from the image, e.g., the image 201, 202, 203, or 203, captured in the image capturing step 1002 after the image capturing step 1002 has been carried out. In the detecting step 1003, the detecting section 81 binarizes the image, e.g., the image 201, 202, 203, or 204, captured by the image capturing assembly 30 with the luminance value of the predetermined threshold value, converts pixels having luminance values equal to or larger than the predetermined threshold value into pixels having the maximum luminance value and pixels having luminance values smaller than the predetermined threshold value into pixels having the minimum luminance value, extracts regions of the pixels having the maximum luminance level except regions where the dividing grooves have been formed by being cut along the projected dicing lines 102, and detects the extracted regions as chip fly-off regions.

The warning step 1004 is a step of warning of at least either one of a cause and a countermeasure according to a region where a chip fly-off has been detected in the detecting step 1003. In the warning step 1004, the warning section 82 refers to the database 300 illustrated in FIG. 8 that is stored in the controller 80 and determines whether a chip fly-off region detected by the detecting section 81 matches the pattern of one of the chip fly-off regions registered in the database 300. Then, if the chip fly-off region detected by the detecting section 81 is determined as matching the pattern of one of the chip fly-off regions registered in the database 300, then the warning section 82 warns of at least either one of the cause and the countermeasure that are associated with the pattern determined as matched in the database 300, and sends the warning to the signaling assembly 70 to enable the signaling assembly 70 to signal the warning.

In the warning step 1004, the display unit 71 of the signaling assembly 70 may signal the warning by displaying a screen, or the lighting unit 72 of the signaling assembly 70 may signal the warning by way of lighting, blinking, or light hues in one of patterns assigned to respective warnings. Moreover, the sounding unit of the signaling assembly 70 may signal the warning by producing sounds in one of patterns assigned to respective warnings. Further, the signaling assembly 70 may transmit a predetermined piece of warning information to a separate communication device.

According to the present embodiment, the warning step 1004 may be carried out at a time at which a chip fly-off is detected on a workpiece 100 after the workpiece 100 has been divided and its image has been captured, before a next workpiece 100 starts to be processed, or may be carried out after a plurality of workpieces 100 have been divided and their images have been captured.

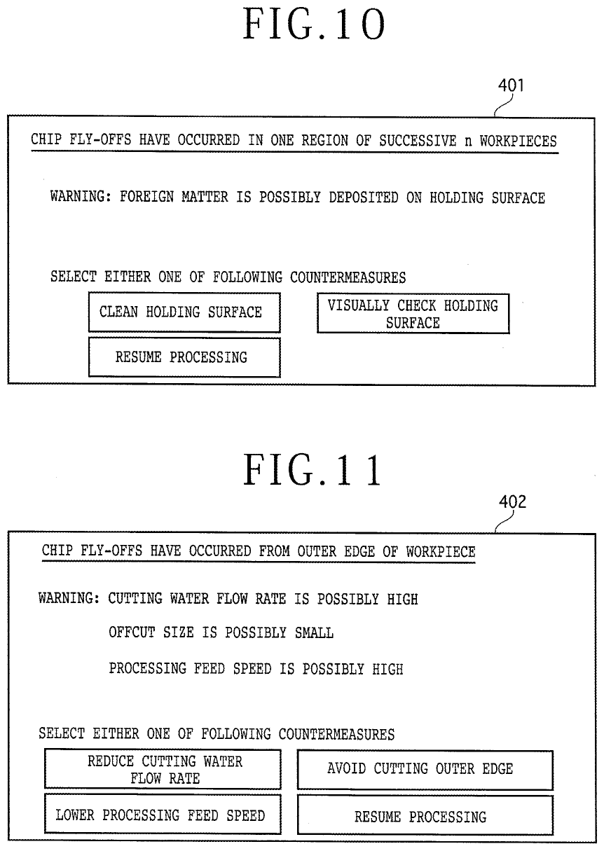

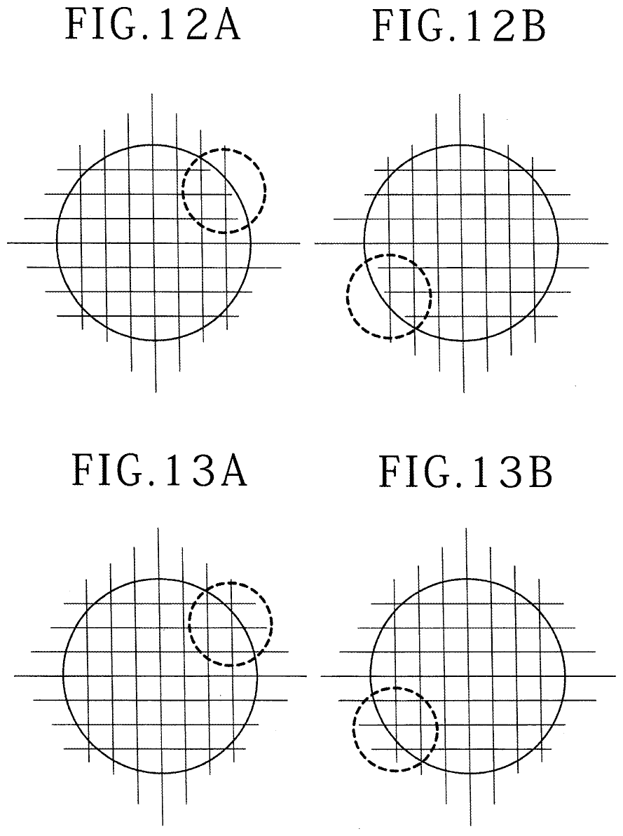

FIGS. 10 and 11 illustrate by way of example respective screens 401 and 402 displayed in the warning step 1004 of the processing sequence illustrated in FIG. 9. FIGS. 12A, 12B, 13A, and 13B illustrate by way of example countermeasures proposed in the warning step 1004 of the processing sequence illustrated in FIG. 9. In each of FIGS. 12A, 12B, 13A, and 13B, a larger solid-line circle represents the outer edge of a workpiece 100, and straight lines extending horizontally and vertically across the solid-line circle represent areas of the workpiece 100 where the workpiece 100 is cut to form dividing grooves therein by the cutting blade 21 in the dividing step 1001.

In the warning step 1004, in a case in which the images 201 and 202 illustrated respectively in FIGS. 6A and 6B have been captured of two successive workpieces 100 in the image capturing step 1002, since the detecting section 81 has detected in the detecting step 1003 that chip fly-offs have occurred in the same upper left portions of the two successive workpieces 100, the warning section 82 determines on the basis of the detected results that the chip fly-offs match the pattern of chip fly-offs occurring successively or with a probability equal to or higher than a predetermined value in one region of at least a desired number (n) of workpieces 100, registered in the database 300. In this case, the warning section 82 displays the screen 401 illustrated in FIG. 10 on the display unit 71 of the signaling assembly 70.

As illustrated in FIG. 10, the screen 401 indicates the determined results that chip fly-offs have occurred successively or with a probability equal to or higher than a predetermined value in one region of at least a desired number (n) of workpieces 100, warning contents regarding a cause of the chip fly-offs that represents the possibility of foreign matter deposited on the holding surface 11 of the holding table 10, and warning contents representing buttons about countermeasures including cleaning and visual checking of the holding surface 11 selectably proposed to the operator. The screen 401 also includes, in addition to the buttons about the countermeasures, a button selectable by the operator to resume the processing of the workpiece 100. When the operator selects either one of the buttons about the countermeasures on the screen 401, the controller 80 switches to a screen for performing the selected countermeasure. When the operator selects the button to resume the processing of the workpiece 100 on the screen 401, the controller 80 resumes the processing of the workpiece 100.

In the warning step 1004, in a case in which the images 203 and 204 illustrated respectively in FIGS. 7A and 7B have been captured of two successive workpieces 100 in the image capturing step 1002, since the detecting section 81 has detected in the detecting step 1003 that chip fly-offs have occurred from the outer edges of the two successive workpieces 100, the warning section 82 determines on the basis of the detected results that the chip fly-offs match the pattern of chip fly-offs occurring from the outer edge of the workpiece 100, registered in the database 300. In this case, the warning section 82 displays the screen 402 illustrated in FIG. 11 on the display unit 71 of the signaling assembly 70.

As illustrated in FIG. 11, the screen 402 indicates the determined results that chip fly-offs have occurred from the outer edges of the workpieces 100, warning contents regarding causes of the chip fly-offs that represent the possibility of a small offcut size, the possibility of a high cutting water flow rate, and the possibility of a high processing feed speed, and warning contents representing buttons about countermeasures including avoiding cutting the workpiece 100 to the outer edge in the chip fly-off region, reducing the cutting water flow rate, and lowering the processing feed speed selectably proposed to the operator. The screen 402 also includes, in addition to the buttons about the countermeasures, a button selectable by the operator to resume the processing of the workpiece 100. When the operator selects either one of the buttons about the countermeasures on the screen 402, the controller 80 switches to a screen for performing the selected countermeasure. When the operator selects the button to resume the processing of the workpiece 100 on the screen 402, the controller 80 resumes the processing of the workpiece 100.

Particularly in the warning step 1004, if chip fly-offs have occurred from the outer edge of the workpiece 100 more noticeably on the entry side of the cutting blade 21, then it is preferable to highlight a warning indicating the possibility of a high flow rate for the cutting water supplied to the entry side of the cutting blade 21. If chip fly-offs have occurred from the outer edge of the workpiece 100 more noticeably in one region, then it is preferable to highlight a countermeasure of avoiding cutting the outer edge of the workpiece 100 in the chip fly-off region and a countermeasure of lowering the processing feed speed.

In the warning step 1004, in a case in which the image 203 illustrated in FIG. 7A has been captured in the image capturing step 1002, the detecting section 81 detects in the detecting step 1003 that chip fly-offs have occurred in three locations on the upper right portion of the outer edge of the workpiece 100. If the operator selects the countermeasure of avoiding cutting the outer edge of the workpiece 100 in the chip fly-off region on the screen 402, the warning section 82 proposes changing the cutting process in the dividing step 1001 on each of subsequent workpieces 100 to prevent chip fly-offs from occurring by forming a dividing groove up to a position spaced a predetermined distance radially inwardly from the outer edge of the workpiece 100, i.e., avoiding cutting the outer edge of the workpiece 100, in an outer edge section covering the three locations, where the chip fly-offs have been detected, on the upper right portion of the outer edge of the workpiece 100 within a broken-line circle illustrated in FIG. 12A.

In the warning step 1004, in a case in which the image 204 illustrated in FIG. 7B has been captured in the image capturing step 1002, the detecting section 81 detects in the detecting step 1003 that chip fly-offs have occurred in three locations on the lower left portion of the outer edge of the workpiece 100. If the operator selects the countermeasure of avoiding cutting the outer edge of the workpiece 100 in the chip fly-off region on the screen 402, the warning section 82 proposes changing the cutting process in the dividing step 1001 on each of subsequent workpieces 100 to prevent chip fly-offs from occurring by forming a dividing groove up to a position spaced a predetermined distance radially inwardly from the outer edge of the workpiece 100, i.e., avoiding cutting the outer edge of the workpiece 100, in an outer edge section covering the three locations, where the chip fly-offs have been detected, on the lower left portion of the outer edge of the workpiece 100 within a broken-line circle illustrated in FIG. 12B.

In the warning step 1004, in a case in which the image 203 illustrated in FIG. 7A has been captured in the image capturing step 1002, the detecting section 81 detects in the detecting step 1003 that chip fly-offs have occurred in three locations on the upper right portion of the outer edge of the workpiece 100. If the operator selects the countermeasure of reducing the flow rate of the cutting water or lowering the processing feed speed on the screen 402, the warning section 82 proposes changing the cutting process in the dividing step 1001 on each of subsequent workpieces 100 to prevent chip fly-offs from occurring by reducing the flow rate of the cutting water or lowering the processing feed speed as selected by the operator in an outer edge section covering the three locations, where the chip fly-offs have been detected, on the upper right portion of the outer edge of the workpiece 100 within a broken-line circle illustrated in FIG. 13A.

In the warning step 1004, in a case in which the image 204 illustrated in FIG. 7B has been captured in the image capturing step 1002, the detecting section 81 detects in the detecting step 1003 that chip fly-offs have occurred in three locations on the lower left portion of the outer edge of the workpiece 100. If the operator selects the countermeasure of reducing the flow rate of the cutting water or lowering the processing feed speed on the screen 402, the warning section 82 proposes changing the cutting process in the dividing step 1001 on each of subsequent workpieces 100 to prevent chip fly-offs from occurring by reducing the flow rate of the cutting water or lowering the processing feed speed as selected by the operator in an outer edge section covering the three locations, where the chip fly-offs have been detected, on the lower left portion of the outer edge of the workpiece 100 within a broken-line circle illustrated in FIG. 13B.

The method of and the apparatus 1 for processing a workpiece according to the present embodiment as arranged above are able to determine and warn of at least either one of a deduced cause of chip fly-offs and a countermeasure against chip fly-offs. Consequently, the method of and the apparatus 1 for processing a workpiece according to the present embodiment are advantageous in that the operator finds it easy to analyze causes of chip fly-offs and to review countermeasures against chip fly-offs.

Further, in a case in which chip fly-offs have been detected in one region of at least a desired number of workpieces 100 in the detecting step 1003, the method of and the apparatus 1 for processing a workpiece according to the present embodiment warns of foreign matter deposited on the holding surface 11 of the holding table 10 and proposes cleaning the holding surface 11 of the holding table 10. Moreover, in a case in which the cutting blade 21 has cut the workpiece 100 while cutting water has been supplied to the processing spot in the dividing step 1001 and chip fly-offs have been detected from the outer edge of the workpiece 100 in the detecting step 1003, the method of and the apparatus 1 for processing a workpiece according to the present embodiment warn of a high cutting water flow rate and propose adjusting the cutting water flow rate. In addition, when chip fly-offs have been detected from the outer edge of the workpiece 100 in the detecting step 1003, the method of and the apparatus 1 for processing a workpiece according to the present embodiment propose formation of a dividing groove in the workpiece 100 up to a position spaced radially outwardly from the outer edge of the workpiece 100 such that the dividing groove terminates short of the outer edge of the workpiece 100 in the chip fly-off region where the chip fly-offs have occurred.

Besides, in a case in which the cutting blade 21 has cut the workpiece 100 in the dividing step 1001 and chip fly-offs have been detected from the outer edge of the workpiece 100 in the detecting step 1003, the method of and the apparatus 1 for processing a workpiece according to the present embodiment propose in the warning step 1004 lowering the processing feed speed at which the cutting blade 21 and the workpiece 100 are processing-fed relatively to each other along the projected dicing lines 102 in the chip fly-off region in the dividing step 1001. As described above, the method of and the apparatus 1 for processing a workpiece according to the present embodiment make it easy for the operator to suitably analyze causes of chip fly-offs and to suitably review countermeasures for preventing device chips from flying off from workpieces by proposing appropriate warnings and countermeasures depending on the processing details of the dividing step 1001 and the pattern of chip fly-offs detected in the detecting step 1003.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a workpiece to divide the workpiece into a plurality of device chips, comprising:
a dividing step of dividing a workpiece held on a holding table to produce a plurality of device chips from the workpiece;
an image capturing step of capturing an image of the workpiece while the dividing step is being carried out or after the dividing step has been carried out;
a detecting step of detecting from the image whether there is a chip fly-off from the workpiece or not and a chip fly-off region where a chip fly-off has occurred; and
a warning step of warning of at least either one of a cause of the chip fly-off and a countermeasure against chip fly-offs according to a region where the chip fly-off has been detected.

2. The method of processing a workpiece according to claim 1, wherein, in a case in which chip fly-offs have been detected in one region of at least a desired number of workpieces in the detecting step, the warning step includes a step of warning of foreign matter deposited on a holding surface of the holding table.

3. The method of processing a workpiece according to claim 1, wherein, in a case in which chip fly-offs have been detected in one region of at least a desired number of workpieces in the detecting step, the warning step includes a step of proposing cleaning a holding surface of the holding table.

4. The method of processing a workpiece according to claim 1, wherein the dividing step includes a step of cutting the workpiece with a cutting blade while cutting water is supplied to a processing spot where the cutting blade cuts the workpiece, and
in a case in which a chip fly-off has been detected from an outer edge of the workpiece in the detecting step, the warning step includes a step of warning of a high flow rate for the cutting water.

5. The method of processing a workpiece according to claim 1, wherein the dividing step includes a step of cutting the workpiece with a cutting blade while cutting water is supplied to a processing spot where the cutting blade cuts the workpiece, and
in a case in which a chip fly-off has been detected from an outer edge of the workpiece in the detecting step, the warning step includes a step of proposing adjusting a flow rate for the cutting water.

6. The method of processing a workpiece according to claim 1, wherein, in a case in which a chip fly-off has been detected from an outer edge of the workpiece in the detecting step, the warning step includes a step of proposing forming in the dividing step a dividing groove in the workpiece up to a position spaced a predetermined distance inwardly from the outer edge of the workpiece such that the dividing groove terminates short of the outer edge of the workpiece in a region where the chip fly-off has occurred.

7. The method of processing a workpiece according to claim 1, wherein the dividing step includes a step of cutting the workpiece with a cutting blade, and
in a case in which a chip fly-off has been detected from an outer edge of the workpiece in the detecting step, the warning step includes a step of proposing in the dividing step lowering a processing feed speed at which the cutting blade and the workpiece are processing-fed relatively to each other along a projected dicing line established on the workpiece in a region where the chip fly-off has occurred.

8. An apparatus for processing a workpiece to divide the workpiece into a plurality of device chips, comprising:
a holding table for holding a workpiece thereon;
a dividing unit which divides the workpiece held on the holding table to produce a plurality of device chips from the workpiece;
an image capturing unit which captures an image of the workpiece while the workpiece is being divided by the dividing unit or after the workpiece has been divided by the dividing unit; and
a controller,
wherein the controller includes
a detecting section which detects a chip fly-off region where a chip fly-off has occurred by processing an image captured of the workpiece by the image capturing unit, and
a warning section which warns of at least either one of a cause of the chip fly-off and a countermeasure against chip fly-offs according to the chip fly-off region detected by the detecting section.
